(19) United States
(12) Patent Application Publication
(10) Pub. No.: US 2012/0104442 A1
(43) Pub. Date: May 3, 2012

(54) LED AND MANUFACTURING METHOD

(75) Inventors: TE-WEN KUO, Hukou (TW); KO-WEI CHIEN, Hukou (TW)

(73) Assignee: ADVANCED OPTOELECTRONIC TECHNOLOGY, INC., Hsinchu Hsien (TW)

(21) Appl. No.: 13/206,536

(22) Filed: Aug. 10, 2011

(30) Foreign Application Priority Data
Oct. 29, 2010 (CN) 201010525436.4

(51) Int. Cl. H01L 33/44

(52) U.S. Cl. 257/98; 438/27; 257/E33.061

(57) ABSTRACT

An LED includes a substrate, an LED chip setting on the substrate and a reflection cup surrounding the LED chip on the substrate. The LED chip electrically connects with two electrodes setting on the substrate. The reflection cup is filled with an encapsulating material. A fluorescent layer is formed by heating the encapsulating material and deposits on an end of the encapsulation away from the LED chip. The fluorescent layer is used for converting light from the LED chip into a specific wavelength.

### BACKGROUND

1. Technical Field

The disclosure relates to light emitting diodes, and particularly to an LED and manufacturing method for the LED.

2. Description of the Related Art

Light emitting diodes (LEDs) have many advantages, such as high luminosity, low operational voltage, low power consumption, compatibility with integrated circuits, easy driving, long term reliability, and environmental friendliness. Such advantages have promoted wide spread use of the LEDs as a light source. Now, light emitting diodes are commonly applied in environmental lighting.

Light from a common LED chip transfers to the specific wavelength via a fluorescent layer; however, the fluorescent layer of the LED is arranged inside the reflection cup and covering the LED chip. Because a distance between a fluorescent materials of the fluorescent layer and the LED chip is not uniform, light from the LED chip traveling through the fluorescent layer is not uniform.

Therefore, it is desirable to provide an LED and method for manufacturing the LED which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present LED and method for manufacturing the LED. Moreover, in the drawings, like reference numerals designate corresponding parts throughout the views.

FIG. 1 is an exemplary embodiment of a schematic view of an LED in accordance with a first embodiment.

FIG. 2 is an exemplary embodiment of a processing flow chart of manufacturing the LED of FIG. 1.

FIG. 3 is an exemplary embodiment of a schematic view of a substrate having electrodes and a reflection cup of the LED of FIG. 1.

FIG. 4 is an exemplary embodiment of a schematic view of an LED chip arranged on the substrate of FIG. 3.

FIG. 5 is an exemplary embodiment of a schematic view of a plurality of fluorescent particles arranged into an encapsulation covering the LED chip of FIG. 4.

FIG. 6 is an exemplary embodiment of a schematic view of a sealing mold covering on the reflecting cup of FIG. 5.

FIG. 7 is an exemplary embodiment of a schematic view of the sealing mold having an anti-adhesion isolating film covering on the reflecting cup of FIG. 5.

FIG. 8 is an exemplary embodiment of a schematic view of inverting the sealing mold and a structure of the LED of FIG. 7.

FIG. 9 is an exemplary embodiment of a schematic view of the sealing mold and the structure of the LED separated.

### DETAILED DESCRIPTION

Embodiments of an LED and method for manufacturing the LED as disclosed are described in detail here with reference to the drawings.

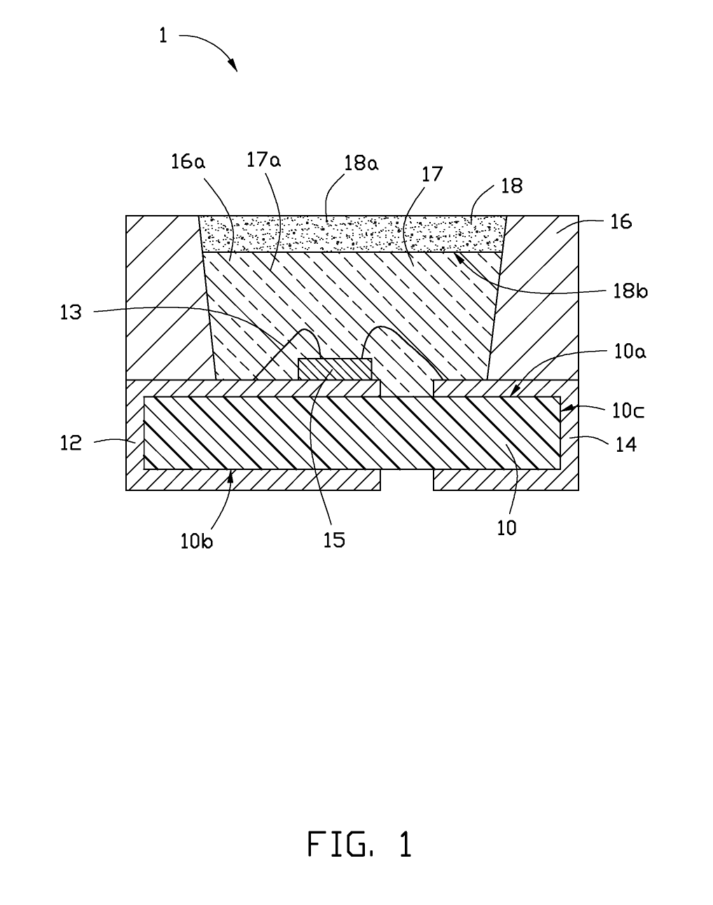

Referring to FIG. 1, an exemplary embodiment of an LED 1 includes a substrate 10, a first electrode 12, a second electrode 14, a reflection cup 16, an LED chip 15, and an encapsulation 17. The first electrode 12 and the second electrode 14 are respectively arranged at two opposite sides of the substrate 10. The LED chip 15 is arranged on the first electrode 12 and respectively connects to the first electrode 12 and the second electrode 14. The reflection cup 16 is arranged on the substrate 10 and forms a recession 16a, substantially as a cone. The LED chip 15 is arranged inside the recession 16a. An amount of encapsulating material 17a is filled into the recession 16a. Thus, the encapsulation 17 covers the LED chip 15.

The substrate 10 includes a top surface 10a, a bottom surface 10b, and a side surface 10c. The top surface 10a is parallel to the bottom surface 10b. The side surface 10c is respectively connected vertically to the top surface 10a and the bottom surface 10b. The first electrode 12 and the second electrode 14 respectively extend from two ends of the top surface 10a of the substrate 10 to the corresponding side surface 10c and the bottom surface 10b. A gap is defined between the first and second electrodes 12, 14 so that they are mechanically and electrically separated from each other.

A plurality of fluorescent particles 18a is arranged in the encapsulation 17. The fluorescent particles 18a are clustered at a top opening of the recession 16a away from the LED chip 15. A fluorescent area 18 is formed by the fluorescent particles 18a and located at a top of the encapsulation 17 to seal the recession 16a.

A separate interface 18b between the fluorescent particles 18a and the encapsulation 17 is parallel to the top surface 10a of the substrate 10. Light from the LED chip 15 travels through the fluorescent area 18, and the fluorescent particles 18 will transfer the light to the specific wavelength.

The encapsulation 17 can be transparent materials, such as PMMA resin, methacrylate resin, polyacrylic acid resin, polycarbonate or polyethylene resin. The fluorescent particles 18a can be sulfide, aluminate, oxide, silicates, or nitrides. In this embodiment, the formula of the fluorescent particles 18a can be Ca₂Al₁₂O₉:Mn, (Ca,Sr,Ba)Al₂O₄:E, Y₃Al₅O₁₂:Ce³⁺(YAG), Tb₃A₁₅O₁₂:Ce³⁺(TAG), BaMgAl₁₀O₁₇:Eu²⁺(Mn²⁺), Ca₂Si₅N₈:Eu²⁺, (Ca,Sr,Ba)S:Eu²⁺, (Mg,Ca,Sr,Ba)₂SiO₄:Eu²⁺, (Mg,Ca,Sr,Ba)₃Si₂O₇:Eu²⁺, Ca₈Mg(SiO₄)₄C₁₂:Eu²⁺, Y₂O₂S:Eu³⁺, CdS, CdTe, or CdSe.

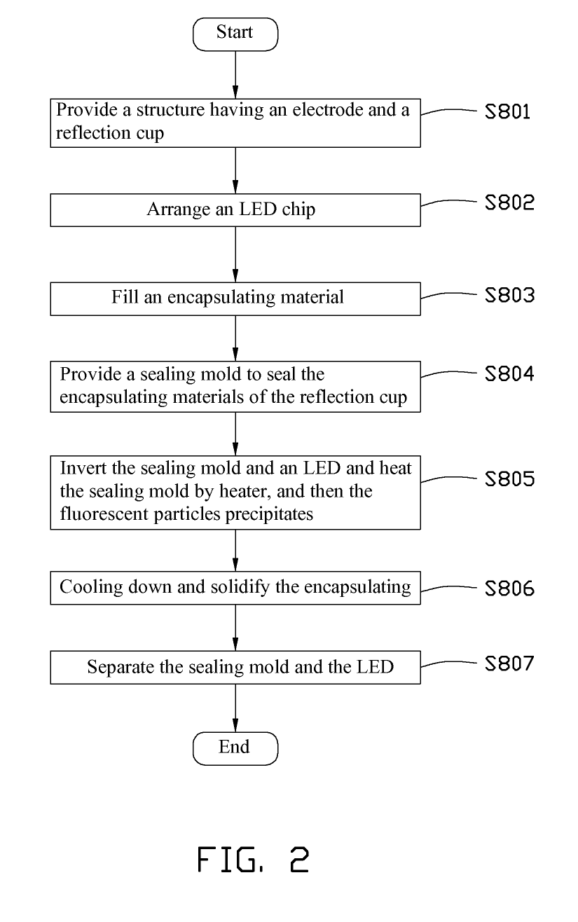

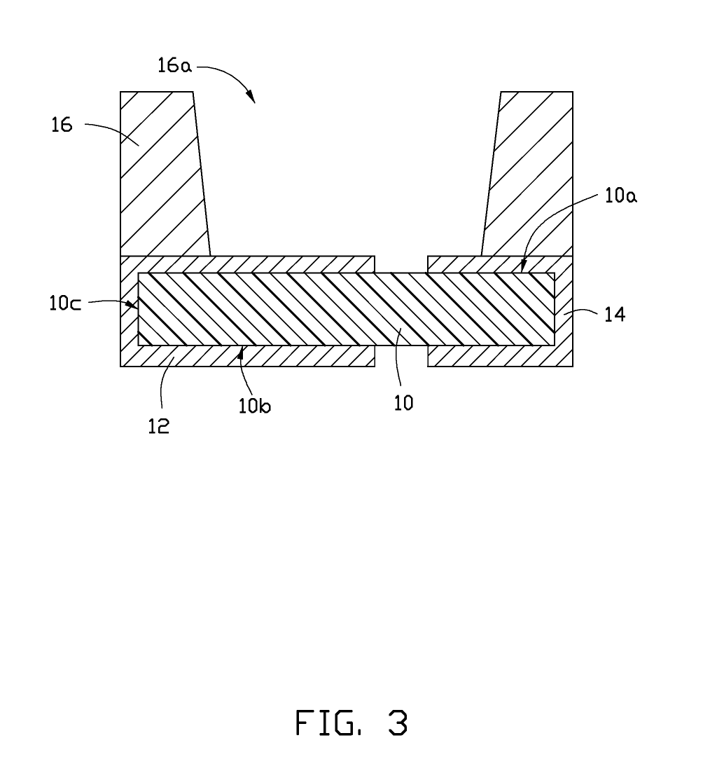

FIG. 2 shows a processing flow of manufacturing the LED 1. Referring to FIGS. 3 and S801 of FIG. 2, provide the substrate 10, the first electrode 12, the second electrode 14, and the reflection cup 16. The first electrode 12 and the second electrode 14 are respectively arranged on the two opposite sides of the substrate 10. The first electrode 12 and the second electrode 14 respectively extend from the top surface 10a of the substrate 10 to the corresponding side surface 10a and the bottom surface 10b.

The reflection cup 16 is arranged on the substrate 10 and forms the recession 16a, substantially like a cone. A portion of the first electrode 12 and the second electrode 14 located at the top surface 10a of the substrate 10 is respectively arranged at a bottom of the recession 16a.

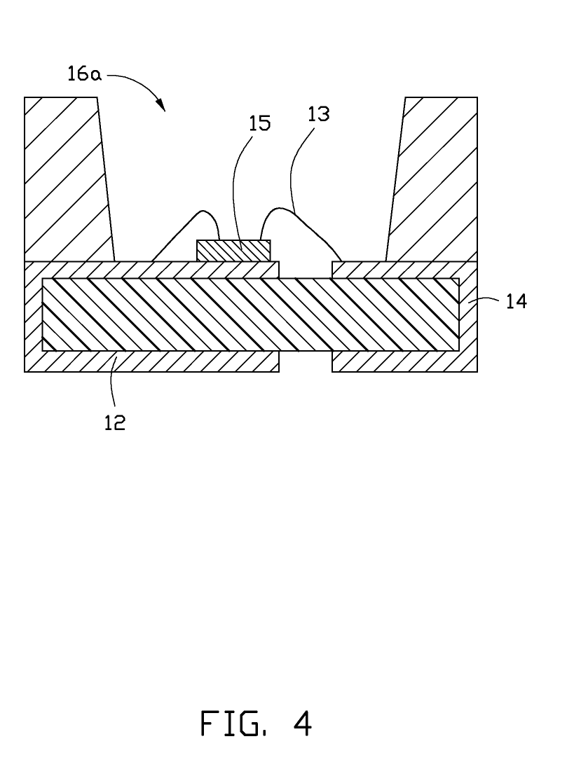

Referring to FIG. 4 and S802 of FIG. 2, the LED chip 15 is mounted on the first electrode 12 of the recession 16a. The LED chip 15 respectively connects to the first electrode 12 and the second electrode 14 of the substrate 10 with wires 13.

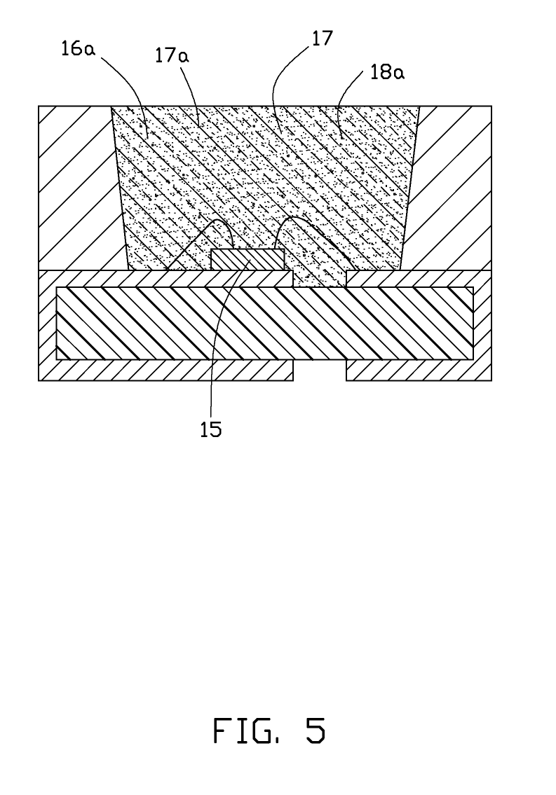

Referring to FIG. 5 and S803 of FIG. 2, utilize the encapsulating material 17a having the plurality of fluorescent particles 18a in the recession 16a and form the encapsulation layer 17 covering the LED chip 15.

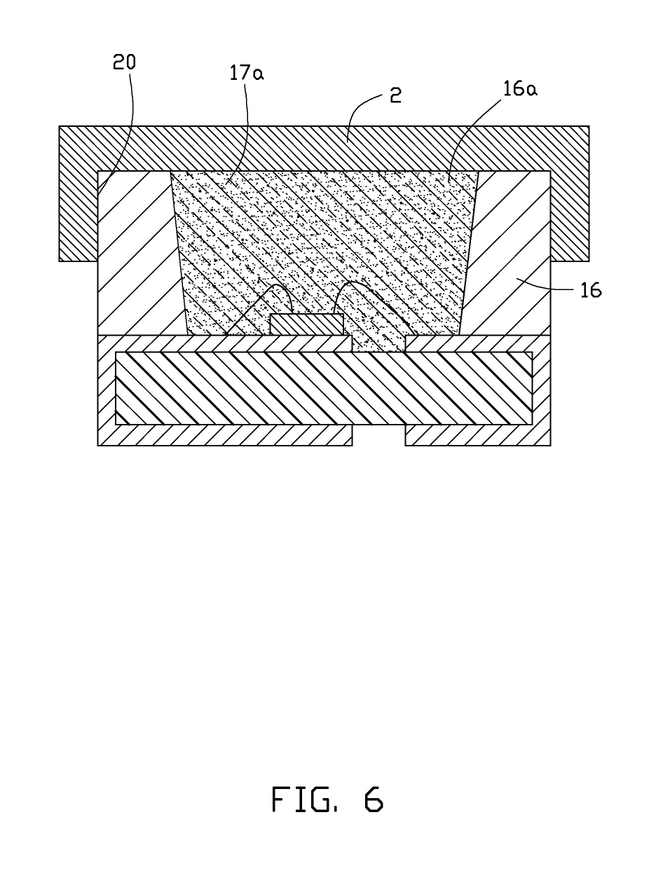

Referring to FIG. 6 and S804 of FIG. 2, provide a sealing mold 2. One end of the sealing mold 2 has a receiving cavity 20 with an opening. The sealing mold 2 covers the reflecting cup 16. Thus, the receiving cavity 20 covers a top of the reflecting cup 16 and seals the encapsulating material 17a in the recession 16a.

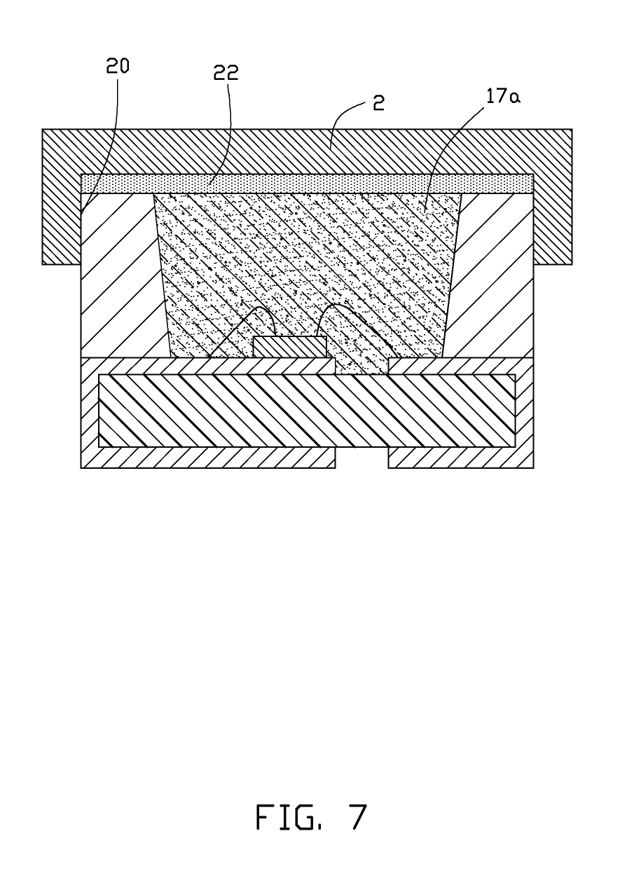

Referring to FIG. 7, an anti-adhesion isolating film 22 is arranged on the bottom of the recession 20. The anti-adhesion isolating film 22 separates the sealing mold 2 and the encapsulating material 17a. Thus, it is convenient for separating the sealing mold 2 and the encapsulating material 17a. The anti-adhesion isolating film 22 is made of polymer materials, such as PTFE glass cloth.

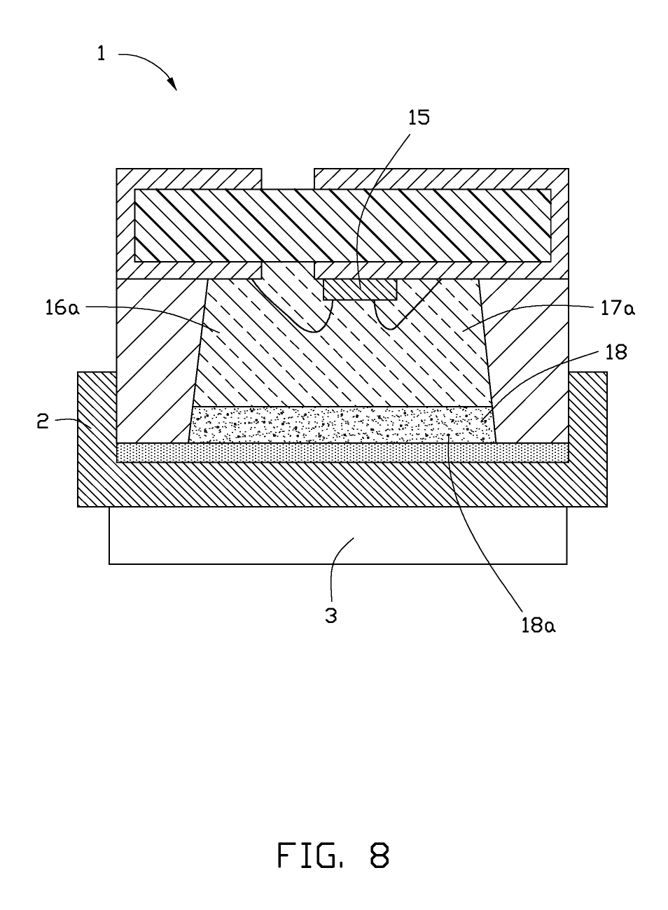

Referring to FIG. 8 and S805 of FIG. 2, invert the sealing mold 2 and the LED 1; heat the sealing mold 2 with a heater. Thus, the encapsulating material 17a transforms to the liquid phase, and then maintains the liquid phase for a certain time. Therefore, the fluorescent particles 18a precipitates downward due to gravity and is clustered at an opening end of one sides of the recession 16a away the LED chip 15 to form the fluorescent area 18.

Referring to S806 of FIG. 2, after the fluorescent area 18 is stable, the heating is stopped. The encapsulating material 17a solidifies at the room temperature. The stable layered fluorescent area 18 is formed at one side of the recession 16a of the encapsulating materials 17a away from the LED chip 15.

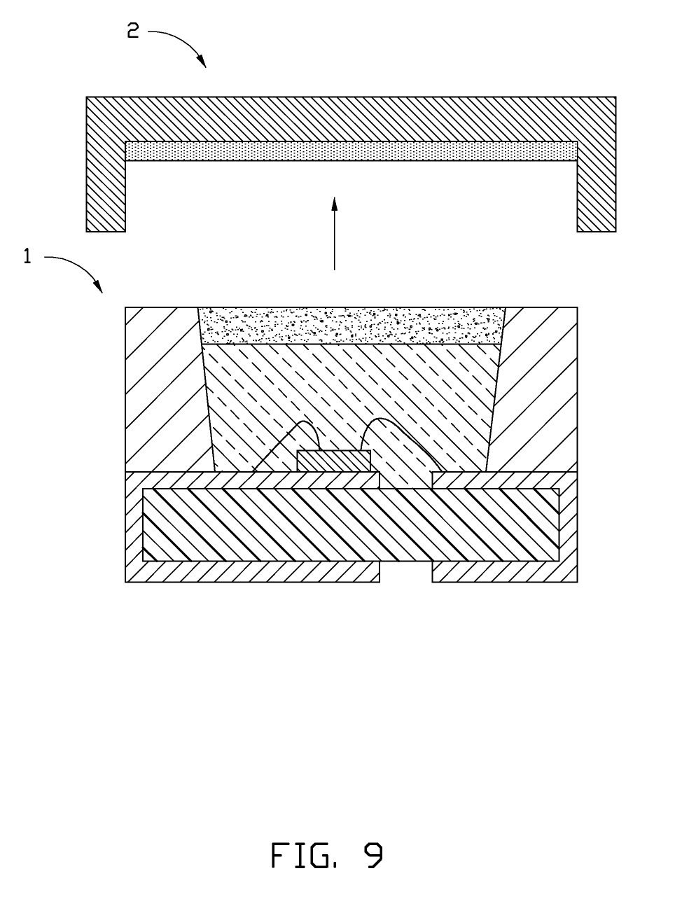

Referring to FIGS. 9 and S807 of FIG. 2, separate the sealing mold 2 and the light emitting diode 1. Thus, the LED 1 in this embodiment is formed. Except the part in which the fluorescent area 18 is located, the other part of the encapsulation 17 is transparent.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An LED, comprising: a substrate, an LED chip mounted on the substrate, and a reflection cup surrounding the LED chip and arranged on the substrate, the LED chip connecting with electrodes of the substrate, wherein an encapsulation is filled into the reflection cup, a fluorescent area is formed in one end portion of the encapsulation away the LED chip, the fluorescent area is used for transferring light from the LED chip to a specific wavelength, the encapsulation being transparent except the one end portion thereof in which the fluorescent area is located.

2. The LED of claim 1, wherein the substrate includes a top surface and a bottom surface parallel to the top surface, and side surfaces respectively perpendicular to the top surface and the bottom surface.

3. The LED of claim 2, wherein the electrodes of the substrate include a first electrode and a second electrode, the first electrode and the second electrode respectively extend from two opposite side of the top surface of the substrate to the corresponding side surfaces and the bottom surface, and the LED chip arranged on the first electrode respectively connects to the first electrode and the second electrode with wires.

4. The LED of claim 2, wherein a separate interface between the encapsulation and the fluorescent area is parallel to the top surface of the substrate.

5. The lamp structure of claim 4, wherein the fluorescent area includes a plurality of fluorescent particles, and chemical composition of the fluorescent particles is Ca₂Al₁₂O₉:Mn, (Ca, Sr, Ba) A₁₂O₄:Eu, Y₃Al₅O₁₂:Ce³⁺(YAG), Tb₃Al₅O₁₂:Ce³⁺(TAG), BaMgAl₁₀O₁₇:Eu²⁺(Mn²⁺), Ca₂Si₅N₈:Eu²⁺, (Ca, Sr, Ba) S:Eu²⁺, (Mg, Ca, Sr, Ba)₂SiO₄:Eu²⁺, (Mg, Ca, Sr, Ba)₃Si₂O₇:Eu²⁺, Ca₈Mg(SiO₄)₄C₁₂:Eu²⁺, Y₂O₂S:Eu³⁺, CdS, CdTe or CdSe.

6. The LED of claim 1, wherein chemical composition of the encapsulation is PMMA resin, methacrylate resin, polyacrylic acid resin, polycarbonate or polyethylene resin.

7. A method for manufacturing an LED, including steps: providing a substrate and a refection cup, a first electrode and a second electrode being arranged at the two opposite ends of the substrate, a refection cup arranged on the substrate and forming a recession;
arranging an LED chip on the first electrode of the recession and connecting to the first electrode and the second electrode with wires;
an encapsulation layer being formed by filling an encapsulating material having a plurality of fluorescent particles into the recession;
sealing the encapsulating material into the recession;
inverting the LED, and heating the encapsulating material, wherein the fluorescent particles precipitate downward at an opening end of one side of the recession away the LED chip to form a fluorescent area;
stabilizing the fluorescent area and stopping heating, and then cooling down to room temperature, and solidifying the encapsulating material.

8. The method for manufacturing the LED of claim 7, wherein at the step of sealing the encapsulating material into the recession, one end of a sealing mold having a receiving cavity having an opening is provided, the sealing mold is brought to cover the reflecting cup, and the receiving cavity covers a top of the reflecting cup.

9. The method for manufacturing the LED of claim 8, wherein an anti-adhesion isolating film is arranged on a bottom of the receiving cavity, the seal mold covers on the reflection cup, and the anti-adhesion isolating film covers the top of the reflection cup.

10. The method for manufacturing the LED of claim 9, wherein the anti-adhesion isolating film is made of polymer material.
